(19) United States
(12) Patent Application Publication
(10) Pub. No.: US 2019/0357378 A1
(43) Pub. Date: Nov. 21, 2019

(54) TWO-PHASE IMMERSION COOLING SYSTEM AND METHOD WITH ENHANCED CIRCULATION OF VAPOR FLOW THROUGH A CONDENSER

(71) Applicant: TAS Energy Inc., Houston, TX (US)

(72) Inventors: Jack Kolar, Houston, TX (US); Jon Benson, Houston, TX (US)

(21) Appl. No.: 15/983,739

(22) Filed: May 18, 2018

(51) Int. Cl. H05K 7/20; F28D 15/02

(52) U.S. Cl. CPC H05K 7/203; H05K 7/20327; H05K 7/20318; F28D 15/025

(57) ABSTRACT

An immersion tank for a two-phase immersion cooling system holds a bath of dielectric heat transfer fluid in liquid phase in a container provided within an outer wall forming the immersion tank. The dielectric heat transfer fluid in vapor phase flows through a channel provided within the outer wall in a generally downward direction. The dielectric heat transfer fluid in vapor phase condenses on one or more condenser snuggly fitted in a shaft portion of the channel. The channel is formed at least by a divider plate located inside the outer wall. The divider plate forms an essentially vertical barrier between a first lateral zone and a second lateral zone of the immersion tank. The condensate flows through one or more opening that are provided at a base portion of the divider plate.

### CROSS-REFERENCE TO RELATED APPLICATIONS

None

### BACKGROUND

This disclosure generally relates to methods and apparatus for cooling electric or electronic components using one or more dielectric heat transfer fluids and, more specifically, to methods and apparatus for enhancing circulation of vapor flow through a condenser.

Conventional electronic components are designed to operate over a specified temperature range with upper limits generally below 70 deg. C. for commercial grade, 85 deg. C. for industrial grade, or 125 deg. C. for military grade; therefore, these components may require cooling such that their internal temperature remains below these upper limits. The cooling can be performed, among other ways, by the vaporization of a dielectric heat transfer fluid, such as perfluorocarbons, fluoroketones, or hydrofluoroethers. Depending on its composition, the dielectric heat transfer fluid may have a boiling temperature at atmospheric pressure that may range from approximately 35 deg. C. to approximately 100 deg. C., such that the boiling temperature at atmospheric pressure is lower than the upper limits at which conventional electronic components are designed to operate. The electronic components are immersed in the dielectric heat transfer fluid in liquid phase. When the surfaces of electronic components in contact with the dielectric heat transfer fluid reach the boiling temperature of the dielectric heat transfer fluid, the dielectric heat transfer fluid located nearby will vaporize, therefore absorbing heat from the electronic components.

For example, in a known two-phase immersion cooling system illustrated in FIGS. 1, 2 and 3, electronic components can be placed near a bottom of a metallic tank 10 which may be thermally and electrically insulated with a skin 12. The metallic tank 10 is filled with a dielectric fluid in liquid phase 14. The dielectric fluid in liquid phase 14 can be in direct thermal contact with the electronic components. In use, the electronic components generate heat. The heat is absorbed by the vaporization of the dielectric fluid. The dielectric fluid in vapor phase 16, having a density much lower than the dielectric fluid in liquid phase 14, rapidly bubbles up above the surface of the liquid (i.e., the top surface of the dielectric fluid in liquid phase 14). Condensers 18 (e.g., coils in which water at a temperature at least 15 deg. C. below the boiling temperature of the dielectric fluid) are placed in bumpouts 20 in the walls of the metallic tank 10. The dielectric fluid in vapor phase 16 flows through the condenser 18 in a generally upward direction. Upon contact with the condensers 18, the dielectric fluid in vapor phase 16 releases heat to the condensers 18 (e.g., increases the temperature of the water circulating in the coils) and returns in liquid phase. The dielectric fluid in liquid phase 14, having a density much higher than the dielectric fluid in vapor phase 16, rapidly drips down toward the bottom of the metallic tank 10. The cycle consisting of the liquid in contact with the electronic components vaporizing, the vapor rising above the liquid, the vapor in contact with the condensers 18 turning into liquid, and the liquid falling through the vapor, allows the transfer of the heat generated by the electronic components to the condenser.

Examples of known condensers include, for small systems (a few kW), radiator-like structures with appropriate finstock. However, for larger systems, the accepted wisdom in the art is that the condenser 18 should be fabricated as banks of enhanced tubes 50 of a type similar to that used in industrial water-cooled chiller condensers. The enhanced efficiency of the tube surfaces enables the condensation of the dielectric fluid in vapor phase 16 in a very limited space on top of the metallic tank 10.

To minimize losses of the dielectric fluid during use of this known two-phase immersion cooling system, the metallic tank 10 is preferably provided with a freeboard space 46 having a height of at least 10 cm above the condensers 18, so that the vapor surface (i.e., the top surface of the dielectric fluid in vapor phase 16) does not reach the top of the metallic tank 10. Further, the top of the metallic tank 10 is sealed by a lid 24 and/or accessory plate 26, which are made of metal or glass, and O-rings or gaskets 22, which are made of elastomers. The accessory plate 26 includes perforations to accommodate, for example, a conduit 28 to provide electrical power to, or signals to or from the electronic components, venting and pressure control means 42, and signals from monitoring means 30 (e.g., temperature sensors and/or float switches). The perforations in the accessory plate 26 are preferably located above the surface of the liquid, and more preferably above the surface of the vapor. The conduit 28 can be potted with resin, and/or have a termination immersed in the liquid phase 14 rather than in the vapor phase 16, because the liquid phase 14 is more viscous than the vapor phase 16, thus the liquid phase 14 is less prone to migration in the interstices between the wires disposed in the conduit 28 than the vapor phase 16. Still further, a secondary condenser 32 may be provided in the venting and pressure control means 42 to condense and retain much of the dielectric fluid in vapor phase 16 that could otherwise be entrained with air vented out of the metallic tank 10.

Moisture in the metallic tank 10 can be managed using a desiccant 44 located in the freeboard space 46. Hydrocarbon oils impurities can be managed using a carbon cartridge, filter and pump assembly 48, located in the liquid phase 14 of the dielectric fluid.

The metallic tank 10 can be operated at atmospheric pressure using the venting and pressure control means 42. Small variations of volume in the metallic tank 10 can be accommodated with the expansion and contraction of bellows 36. Large increases of volume in the metallic tank 10, for example, caused by degassing of the dielectric fluid in liquid phase 14, or the rise of the surface of the vapor, can be accommodated by opening a solenoid valve 42 triggered by the bellows 36 actuating a switch 38 upon reaching a fully expanded position. Large decreases of volume in the metallic tank 10, for example, caused by a drop of the surface of the vapor, can be accommodated by opening the solenoid valve 42 triggered by a vacuum switch 34.

Other known two-phase cooling systems are described in U.S. Pat. Appl. Pub. No. 2014/0218858.

With the advancement of High-Performance Computing, where large numbers of computers are assembled or collocated into a unit or data center for simulation or encryption computing, there is a continuing need in the art to accommodate for larger densities of heat to be transferred out of electric or electronic components, sometimes in excess of 4000 Watts per square feet. Thus, there is a continuing need in the art for improved two-phase immersion cooling systems and methods.

### BRIEF SUMMARY OF THE DISCLOSURE

In one aspect, the disclosure describes an immersion tank for a two-phase immersion cooling system. The immersion tank has, in a lateral direction, a first zone, and at least a second zone located on a side of the first zone, and in a vertical direction, a lower space, a middle space, and an upper space. The immersion tank comprises an outer wall forming the immersion tank, a container for holding a bath of dielectric heat transfer fluid in liquid phase, and one or more condenser. The container may be located in the first zone and in the lower space. One condenser may be located in the second zone and in the middle space.

The immersion tank may comprise a channel in which the one or more condenser may be snuggly fitted. The channel may include an inlet and an outlet. The inlet of the channel may be open to a space above the container. The outlet of the channel may be formed by one or more openings provided through a base portion of one or more divider plates. In use, the dielectric heat transfer fluid in vapor phase may flow through the channel in a generally downward direction and may condense on the one or more condenser.

The inlet of the channel may be located above the a shaft portion of the channel. The outlet may be located below the shaft portion. The one or more condenser may preferably be snuggly fitted in the shaft portion. The shaft portion may be formed at least by the one or more divider plates located inside the outer wall. The shaft portion may further be formed by a lateral portion of the outer wall. The shaft portion may preferably be vertical.

The channel may further include a vapor duct located above the shaft portion. The vapor duct may include the inlet of the channel. The vapor duct may be formed at least by an upper portion of the outer wall of the immersion tank. The vapor duct may further be formed by a lateral portion of the outer wall of the immersion tank. The vapor duct may include a high spot formed by an upset of the upper portion of the outer wall of the immersion tank. A height of the vapor duct may be at least as large as a width of one condenser.

The channel may further include a liquid funnel located below the shaft portion. The liquid funnel may include the outlet of the channel. The liquid funnel may be formed at least by a base portion of one or more divider plates located inside the immersion tank. The liquid funnel may further be formed by a lateral portion of the outer wall of the immersion tank. The lateral portion of the outer wall may preferably be slanted.

The one or more divider plate may be located inside the outer wall and may form an essentially vertical barrier between the first zone the second zone. The one or more opening forming the outlet of the channel may be provided at a base portion of the one or more divider plate. The one or more divider plate may extend vertically from a slanted portion of the outer wall of the immersion tank to at least a level approximately as high as a top of one condenser. The one or more divider plate may extend axially along an entire length of the immersion tank. A top of the one or more divider plate may be offset from a top of the immersion tank by at least a width of one condenser.

In another aspect, the disclosure describes the immersion tank comprises an outer wall forming the immersion tank, a container for holding a bath of dielectric heat transfer fluid in liquid phase, at least one condenser for condensing dielectric heat transfer fluid from a vapor phase to a liquid phase, a divider plate configured such that a dielectric heat transfer vapor is directed to enter into a top of the at least one condenser and the dielectric heat transfer vapor flows downward though the at least one condenser. The divider plate may further be configured such that the dielectric heat transfer vapor is hindered from entering a bottom of the condenser. In some embodiments, the at least one condenser includes a plurality of serpentine coils, and a plurality of transverse fins that span essentially over an entire height of the one or more condenser.

### BRIEF DESCRIPTION OF THE DRAWINGS

For a more detailed description of the embodiments of the disclosure, reference will now be made to the accompanying drawings, wherein:

FIG. 1 is an exploded view of a known two-phase immersion cooling system;

FIG. 2 is a perspective view of a known condenser for use in a two-phase immersion cooling system;

FIG. 3 is a sectional view of a known two-phase immersion cooling system;

FIG. 4 is a perspective view of an immersion tank suitable for use in a two-phase immersion cooling system in accordance with an embodiment;

FIG. 5 is a side view of the immersion tank shown in FIG. 4;

FIG. 5A is a schematic of a portion of the immersion tank shown in FIG. 4;

FIG. 6 is a top view of the immersion tank shown in FIG. 4;

FIG. 7 is a perspective view of a condenser in accordance with an embodiment;

FIG. 8 is a perspective view of a first end portion of the condenser shown in FIG. 7; and

FIG. 9 is a perspective view of a second end portion of the condenser shown in FIG. 7.

### DETAILED DESCRIPTION

It is to be understood that the following disclosure describes several exemplary embodiments for implementing different features, structures, or functions of the invention. Exemplary embodiments of components, arrangements, and configurations are described below to simplify the disclosure; however, these exemplary embodiments are provided merely as examples and are not intended to limit the scope of the invention. Additionally, the disclosure may repeat reference numerals and/or letters in the various exemplary embodiments and across the Figures provided herein. This repetition is for the purpose of simplicity and clarity and does not in itself dictate a relationship between the various exemplary embodiments and/or configurations discussed in the various Figures. Finally, the exemplary embodiments presented below may be combined in any combination of ways, i.e., any element from one exemplary embodiment may be used in any other exemplary embodiment, without departing from the scope of the disclosure.

All numerical values in this disclosure are approximate values unless otherwise specifically stated. Accordingly, various embodiments of the disclosure may deviate from the numbers, values, and ranges disclosed herein without departing from the intended scope. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

As one having ordinary skill in the art will appreciate, various entities may refer to the same elements by different names, and as such, the naming convention for the elements described herein is not intended to limit the scope of the invention, unless otherwise specifically defined herein. Further, the naming convention used herein is not intended to distinguish between components that differ in name but not function.

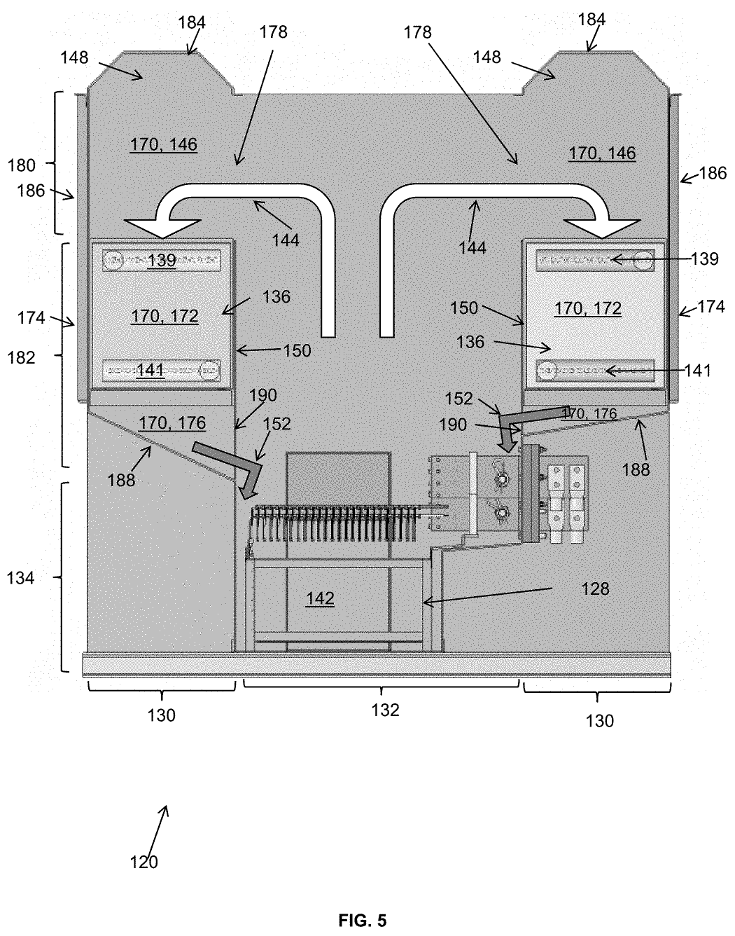

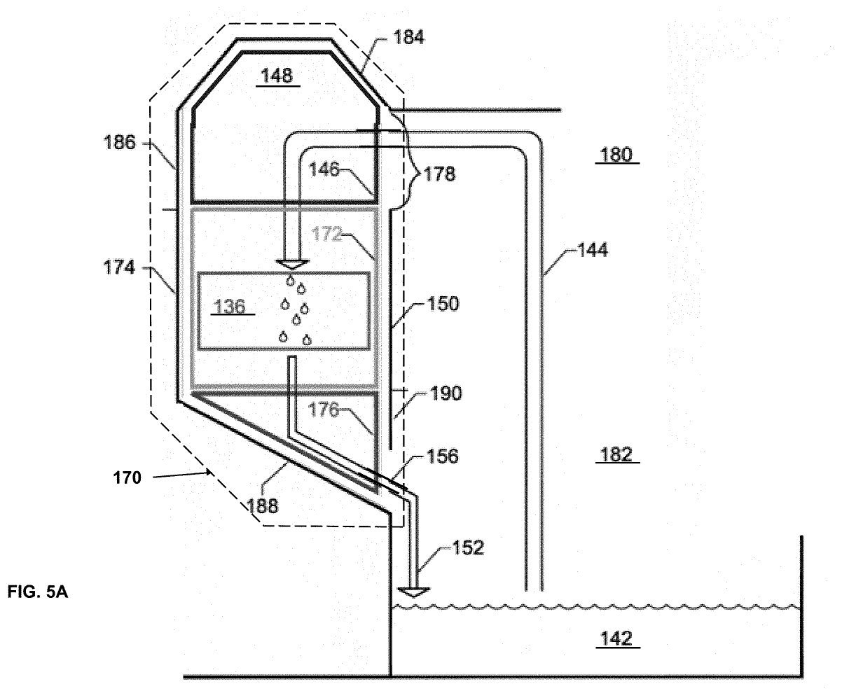

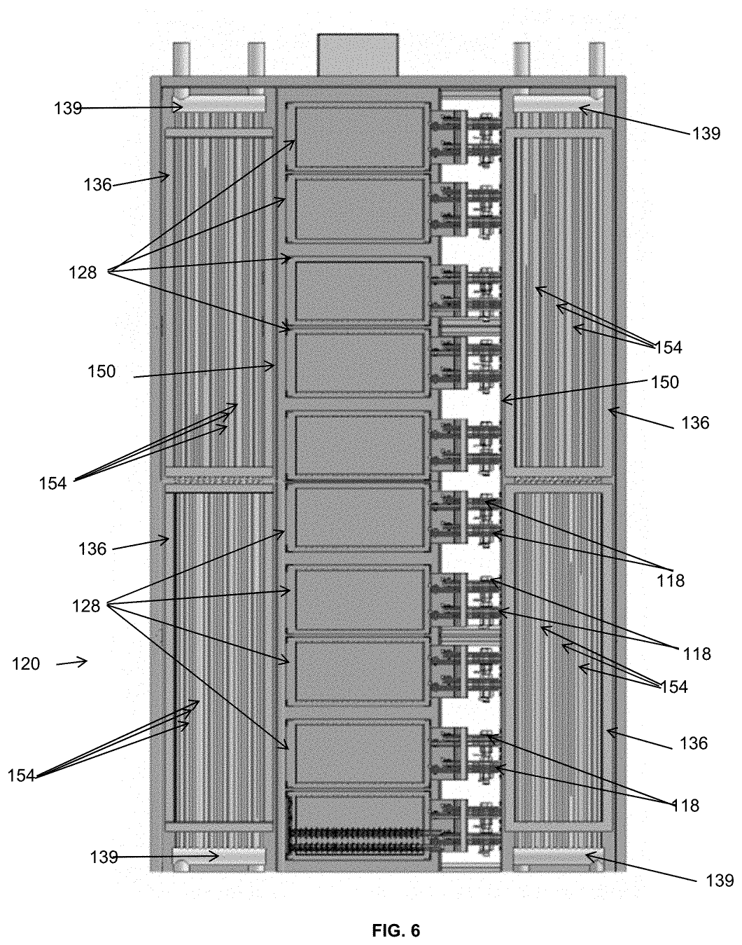

Referring to FIGS. 4, 5 and 6, an example embodiment of an immersion tank 120 implementing a two-phase immersion cooling system is illustrated. One or more immersion tank can be collocated into a unit or data center. The immersion tank 120 is preferably but not necessarily a sealed vessel. The immersion tank 120 has, in the lateral direction, a central zone 132 and two distal zones 130, each of the two distal zones 130 being located on the side of the central zone 132. Electric or electronic components to be cooled may be assembled on one or more board 160. The one or more board 160 can be disposed essentially vertically in modular case 128. The modular case 128 can be immersed, preferably entirely immersed, into a container 142 holding a bath of dielectric heat transfer fluid in liquid phase. A circulating fluid, typically but not exclusively water, is passed through one or more condenser 136. In the foregoing, phase transitions (liquid to vapor and vapor to liquid) and convection of the dielectric heat transfer fluid occurring in the immersion tank 120 are used to absorb the heat generated by the electric or electronic components and to release the heat to the circulating fluid. Thus, the electric or electronic components are cooled while the circulating fluid is warmed.

In the example embodiment shown in FIGS. 4, 5, 5A, and 6, the container 142 used for holding the bath of dielectric heat transfer fluid in liquid phase is located in a lower space 134 of immersion tank 120. Each of the one or more condenser 136 is located in any of the distal zones 130, above the top level of the bath of dielectric heat transfer fluid in liquid phase.

In other embodiments, the relative positions of the condenser and the bath of dielectric heat transfer fluid in liquid phase can be switched, such that a bath of dielectric heat transfer fluid in liquid phase may be located in each of the distal zones of the immersion tank, and the condenser may be located in the central zone of the immersion tank, above the top level of the bath of dielectric heat transfer fluid in liquid phase.

Without being limited by any working principle, a circulation flow pattern configuration may advantageously be utilized to draft the vapor of dielectric fluid bubbling out of the bath of dielectric heat transfer fluid into the condenser 136 and to generate a circulation pattern 144 of the dielectric heat transfer fluid in vapor phase, therefore increasing the efficiency of the condenser 136. Indeed, the vapor condensation may create a low-pressure zone that drafts the vapor toward the entire upper surface at the top of the condenser 136. The pressure at the top of condenser 136 may be lower than the pressure of vapor phase at the top surface of the dielectric fluid in liquid phase. This lower pressure may tend to draft the vapor phase within the central zone 132, through the middle space 182, and toward the upper space 180, and to promote the deflection of the flow of vapor phase within the upper space 180, toward the distal zone 132 and the top of the condenser 136. In addition, the progressive condensing of the vapor phase into a liquid phase within condenser 136 may further cause a slight pressure decrease between the top and the bottom of condenser 136. This slight pressure decrease may further draw down the vapor phase through the condenser 136, initiate and accelerate the circulation pattern 144. For example, gravity causes the liquid phase generated by the condensation of the vapor phase to drain downwards within the condenser 136. The draining of the liquid phase may create a siphon-like action which further lowers the pressure and promotes draw down of the vapor phase through the condenser 136. Thus, the vapor phase and the liquid phase flow in a downward direction through the condenser 136.

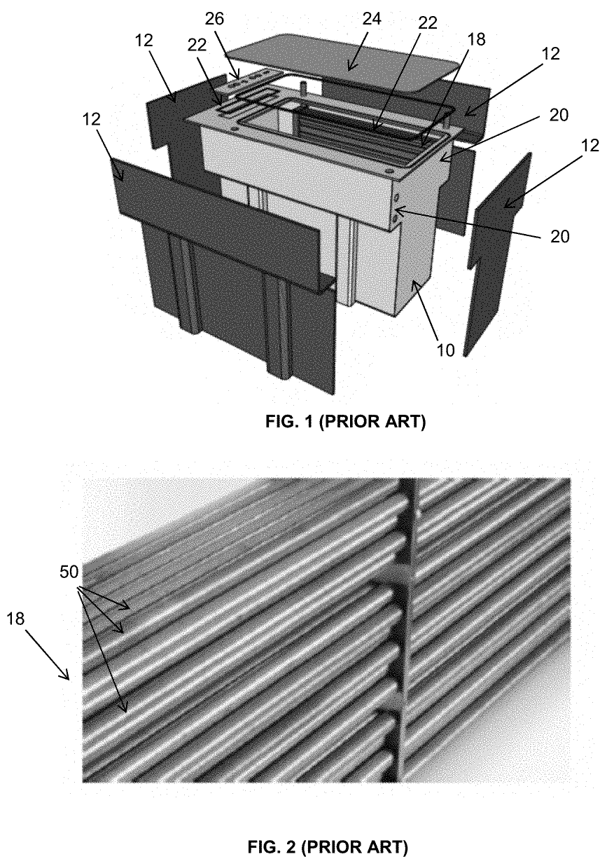

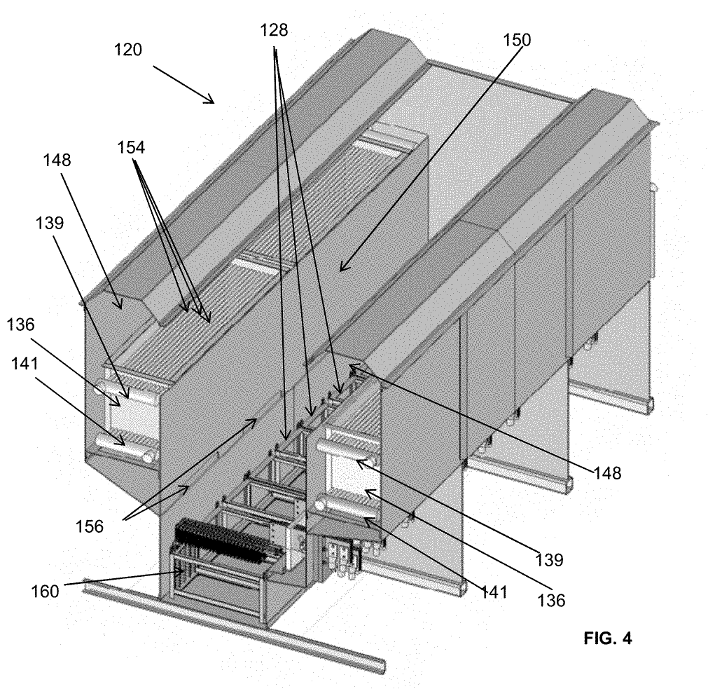

For example, the circulation pattern 144 configuration may be efficiently obtained when the condenser 136 snuggly fits in a vertical portion of a channel 170. As used herein, a channel refers to a structure that encloses a passage between at least two disjoint apertures, wherein one of the two disjoint apertures may form an inlet and the other of the two disjoint apertures may form an outlet. The channel 170 may be formed by a combination of portions of the walls of the immersion tank 120, and divider plates. The channel 170 is configured to guide the flow of the dielectric fluid in vapor phase through the condenser 136 in a generally downward direction. The flow direction of the vapor phase through the condenser 136 of the immersion tank 120 is thus opposite from the flow direction of the vapor phase through the condenser 18 of the known two-phase immersion cooling system illustrated in FIGS. 1, 2 and 3, where the flow of vapor phase is in a generally upward direction, and opposite to the flow of the liquid phase. In other words, in the embodiment shown in FIGS. 4, 5, 5A, and 6, the vapor phase first circulates upwards in the central zone 132, then the flow of vapor phase is deviated in the upper zone 180 until the vapor phase circulates downwards to enter the condenser 136 from the top of the condenser. Finally, the vapor phase circulates downwards through the condenser 136 in the distal zone 130. In contrast, in the known two-phase immersion cooling system illustrated in FIGS. 1, 2 and 3, the vapor phase directly enters the condenser 18 from the bottom of the condenser with relatively minimal turning of the vapor.

In the example embodiment shown in FIGS. 4, 5, 5A, and 6, the channel 170 has an inlet 178 open to an upper space 180 of the immersion tank 120. The channel 170 comprises a vapor duct 146, a vertical portion or shaft portion 172, and a liquid funnel 176. The vapor duct 146 is located vertically above the condenser 136. The shaft portion 172 is formed by one or more divider plate 150 and a vertical lateral portion 174 of the outer wall of the immersion tank 120. The liquid funnel 176 is located vertically below the condenser 136. The channel 170 has an outlet open to a middle space 182 of the immersion tank 120, for example above the top level of the bath of dielectric heat transfer fluid. The outlet may be formed by one or more openings 156 included in the divider plate 150.

In other embodiments where the bath of dielectric heat transfer fluid in liquid phase is located in one or more distal zones of the immersion tank, a channel inlet may be open to an upper space of one of the distal zones (above one of the baths), and a channel outlet may be open to a middle space of the immersion tank.

In the example embodiment shown in FIGS. 4, 5, 5A, and 6, the container 142 used for holding the bath of dielectric heat transfer fluid in liquid phase, while located in the central zone 132, is not located exactly in the center of the immersion tank 120. The condenser 136 located in a distal zone 130 can be identical to a condenser 136 located in another distal zone 130, but the rates at which circulating fluid is passed through the coils of the condensers located on both sides preferably differ from each other to compensate for the dissymmetry. Alternatively, the condenser 136 located in one distal zone 130 may have different size coils from the condenser 136 located in another distal zones 130 to compensate for the dissymmetry of the vapor circulation flowing through a vapor duct 146.

In other embodiments, the bath of dielectric heat transfer fluid in liquid phase may be located exactly in the center of the immersion tank, therefore making the design of the immersion tank more symmetric. In such embodiments, all the condensers may be identical.

In the example embodiment shown in FIGS. 4, 5, 5A, and 6, the vapor duct 146 is formed by an upper portion 184 of the outer wall, and a vertical lateral portion of the outer wall 186. The vapor duct 146 may be at least as high as a width of the condenser 136. The divider plate 150 may form an essentially vertical barrier between the central zone 132, in which the bath of dielectric heat transfer fluid is located, and the one of the two distal zones 130, in which the condenser 136 is located. The divider plate 150 may be configured such that the upward path flow of vapor from the top surface of the dielectric fluid in liquid phase through the coils of the condenser 136 is hindered or prevented. The divider plate 150 can extend axially along the entire length of the immersion tank 120. The divider plate 150 extends vertically from a slanted lateral portion 188 of the outer wall of the immersion tank 120 to at least a level approximately as high as a top of the condenser 136. The top of the divider plate 150 is offset from the top of the immersion tank 120 by at least a width of the condenser 136. The condenser 136 can span a substantial portion of an entire length of the immersion tank 120. The condenser 136 is preferably disposed adjacent to the vertical lateral portion 174 of the outer wall of the immersion tank 120 so that there is little to no space between the vertical lateral portion 174 of the outer wall and the condenser 136 for the dielectric heat transfer fluid in vapor phase to pass. Similarly, the condenser 136 is preferably disposed adjacent to the divider plate 150, so that there is little to no space between the divider plate 150 and the condenser 136 for the dielectric heat transfer fluid in vapor phase to pass. The liquid funnel 176 is formed by the slanted lateral portion 188 of the outer wall, and a base portion 190 of the divider plate 150. The divider plate 150 may be vapor or liquid tight but for the one or more openings 156 provided in the base portion 190 of the divider plate 150. The one or more openings 156 are preferably equally distributed along the entire length of the immersion tank 120. The cumulated length of the one or more openings 156 may be approximately half of the entire length of the immersion tank 120 or more. The openings 156 have preferably a size sufficiently small to limit or entirely avoid inflow of dielectric heat transfer fluid in vapor phase into the liquid funnel 176, and sufficiently large to permit outflow of dielectric heat transfer fluid in vapor phase that has not condensed at the condenser 136. For example, the openings 156 have a size slightly (e.g., 10%) larger than the minimum size required to let the liquid condensed at the condenser 136 flow back to the bath of dielectric heat transfer fluid, using flow path 152 along the slanted lateral portion 188 of the outer wall of the immersion tank 120. In some embodiments, some of the openings 156 may be equipped with flappers (not shown) that further close the openings 156 when the flow of liquid condensate is low so that counterflow of vapor is further minimized or even prevented.

In some embodiments, the vapor duct 146 may include one or more high spot 148. The high spot 148 can be located at the top of the vapor duct 146. The high spot 148 may be formed by an upset of the upper portion 184 of the outer wall of the immersion tank 120. The high spot 148 may extend axially along the entire length of the immersion tank 120. The high spot 148 may be located above the condenser 136. The high spot 148 may be used to capture light gases that may otherwise foul the vapor of dielectric heat transfer fluid.

In other embodiments, the upper surface at the top of the condenser 136 may be slanted away from a horizontal surface, for example, the height of the upper surface at the top of the condenser 136 may decrease as a function of the distance from the central zone 132.

Without being limited by any working principle, when the immersion tank 120 is entirely filled with dielectric heat transfer fluid in liquid and vapor phases in thermodynamic equilibrium, the pressure in the immersion tank 120 and the temperature in the immersion tank 120 are related by the phase transition boundary of the phase diagram. In such case, when the pressure in the immersion tank 120 is allowed to vary, the immersion tank 120 can be operated at any pressure and temperature point that lies on the phase transition boundary of the phase diagram of the dielectric heat transfer fluid.

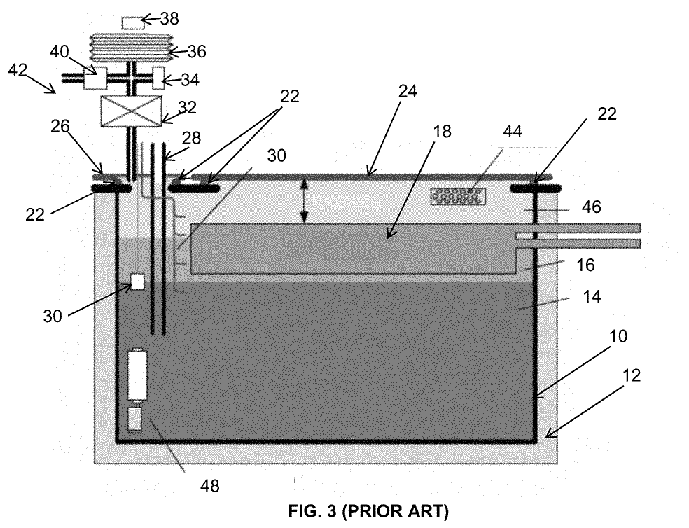

The immersion tank 120 described herein is preferably a sealed vessel in which pressure may vary. In contrast with the prior art example described in the background section, the immersion tank 120 is preferably devoid of the means for specifically maintaining atmospheric pressure. The immersion tank 120 is preferably operated at a pressure lower than the atmospheric pressure. It is well known that the temperature at the phase transition boundary decreases when the pressure at the phase transition boundary decreases. Thus, the immersion tank 120 is preferably designed for operating in usual conditions with a vapor phase at a temperature lower (e.g., at least 5 deg. C. lower) than the boiling temperature at atmospheric pressure of the dielectric heat transfer fluid. In particular, the condenser 136 is preferably configured or sized in a way such that it can transfer heat to the circulating fluid at at least the same rate heat is generated by the electric or electronic components, even when the vapor phase is at a temperature lower than the boiling temperature at atmospheric pressure of the dielectric heat transfer fluid. In other words, when the immersion tank 120 operating in usual conditions is at thermal equilibrium, the temperature in the immersion tank 120 can remain lower than the boiling temperature at atmospheric pressure of the dielectric heat transfer fluid. In contrast, the known two-phase immersion cooling system illustrated in FIGS. 1, 2 and 3 is only required to operate at usual conditions with a vapor phase at a temperature equal the boiling temperature at atmospheric pressure of the dielectric heat transfer fluid. Accordingly, compared to the known condenser 18 illustrated in FIG. 2, the condenser 136 can appear overdesigned.

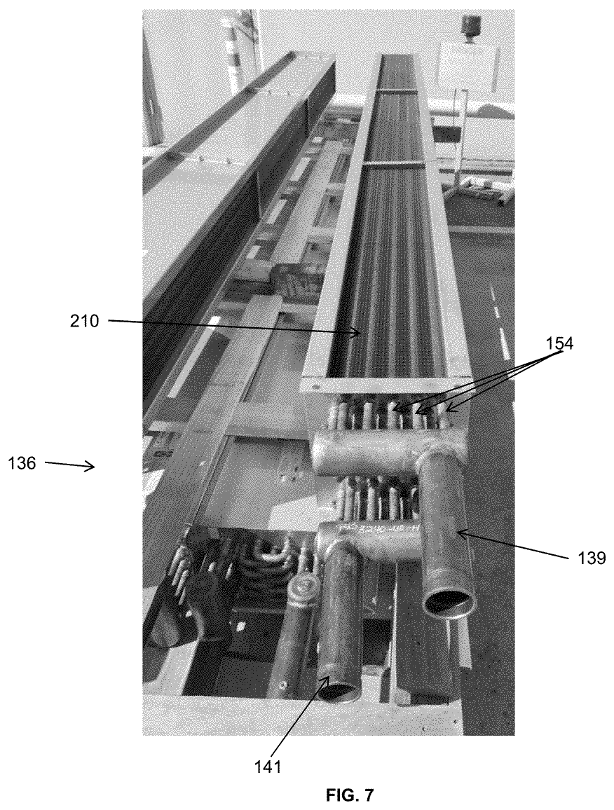

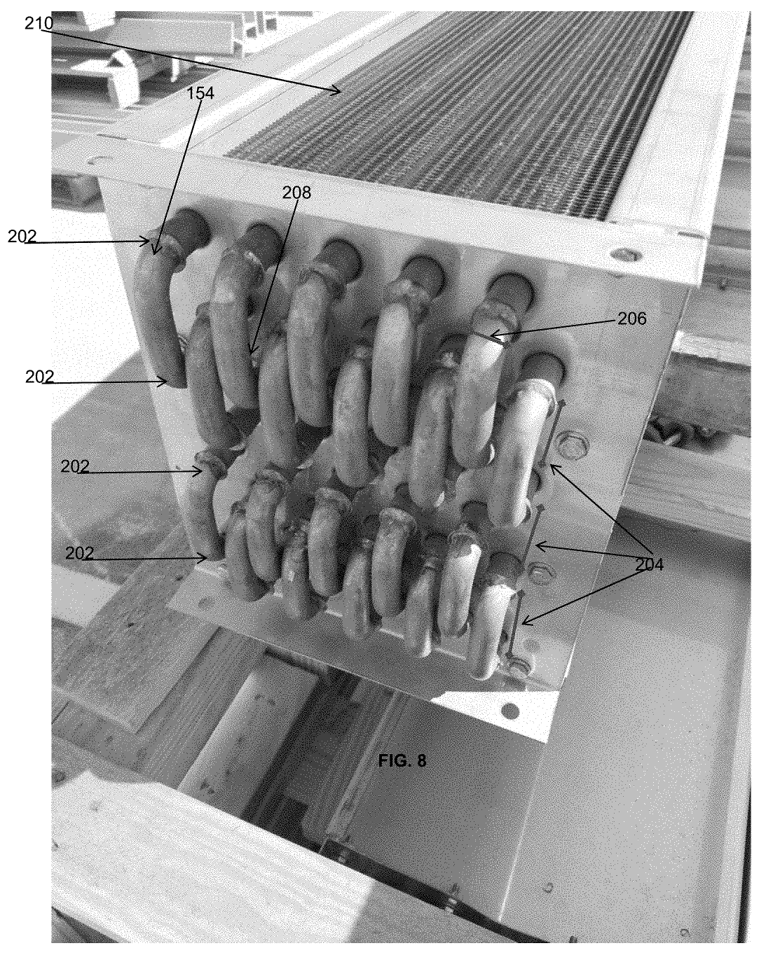

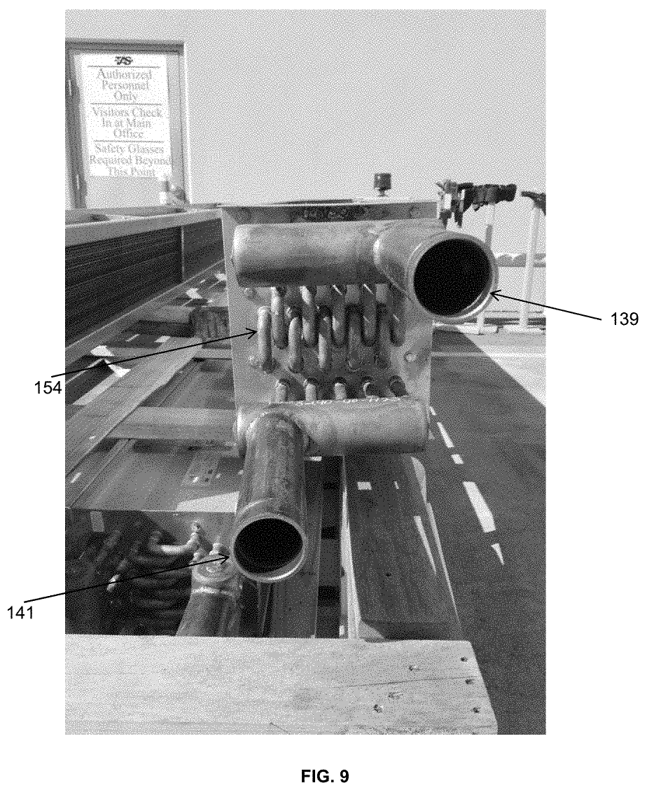

To increase the heat transfer capacity of the condenser 136 while keeping the size of the condenser 136 reasonably small, as well as achieving other objectives, the condenser 136 may be designed in accordance with one or more aspects of the condenser 136 illustrated in FIGS. 7, 8, and 9. For example, the one or more condenser 136 provided in the immersion tank 120 has a surface area that is sized such that heat can be transferred to the circulating fluid at the same rate that heat generated by the electric or electronic components even when the vapor temperature is only 5 deg. C. above the temperature of the circulating fluid entering the condenser 136. The condenser 136 may allow a sufficient flow rate of the circulating fluid such that the temperature of the circulating fluid leaving the condenser 136 is only 2 deg. C. above the temperature of the circulating fluid entering the condenser 136.

In the example embodiment shown in FIGS. 7, 8, and 9, the condenser 136 has a plurality of serpentine coils 154, each of the plurality of serpentine coils 154 including at least four, and preferably six horizontal passes 202. All of the plurality of serpentine coils 154 preferably have an inlet connected to a distribution inlet 141 of the condenser 136. The distribution inlet 141 is, in turn, connected to a source of relatively colder circulating fluid. All of the plurality of serpentine coils 154 preferably have an outlet connected to a collection outlet 139 of the condenser 136. The collection outlet 139 is, in turn, connected to a discharge of relatively warmer circulating fluid.

For example, each of the plurality of serpentine coils 154 have passes 202 that can be distributed vertically. Consecutive passes 202 of any of the plurality of serpentine coils 154 can be separated by a first distance 204 that is approximately equal to two times the diameter 206 of the coils. Serpentine coils 154 that are adjacent can be distributed horizontally vis-a-vis one another, for example, staggered, and/or separated by a second distance 208 that is less than the diameter 206 of the coils.

A plurality of transverse fins 210 may be coupled to any of the plurality of serpentine coils 154. The transverse fins 210 increase the area on which the dielectric heat transfer fluid can condense. For example, all of the plurality of plurality of transverse fins 210 can be disposed vertically, essentially perpendicularly to any of the plurality of serpentine coils 154. Any of the plurality of transverse fins 210 can be coupled to all of the serpentine coils 154. The transverse fins 210 preferably span essentially an entire height of the condenser 136. In contrast with enhanced tubes illustrated in FIG. 2, the dielectric heat transfer fluid can flow down along a surface of the transverse fins 210 without having to form a liquid drop in vapor, which may be advantageous when dielectric heat transfer fluid has a high internal cohesion and/or high adhesion with the materials making the condenser 136. Thus, the transverse fins 210 can be used for limiting the thickness of the film of dielectric heat transfer fluid that has condensed on the serpentine coils 154 and/or the transverse fins 210.

In some embodiments, an immersion tank for a two-phase immersion cooling system having a capacity of at least one hundred kilo-Watts may comprise one or more condenser. The one or more condenser may include a plurality of serpentine coils and a plurality of transverse fins that span essentially over an entire height of the one or more condenser.

While the disclosure is susceptible to various modifications and alternative forms, specific embodiments thereof are shown by way of example in the drawings and description. It should be understood, however, that the drawings and detailed description thereto are not intended to limit the claims to the particular form disclosed, but on the contrary, the intention is to cover all modifications, equivalents, and alternatives falling within the scope of the claims.

What is claimed is:

1. An immersion tank for a two-phase immersion cooling system, comprising:
an outer wall forming the immersion tank;
a container for holding a bath of dielectric heat transfer fluid in liquid phase;
a channel including an inlet, a shaft portion, and an outlet, wherein the inlet is located above the shaft portion, and wherein the outlet is located below the shaft portion; and
one or more condenser snuggly fitted in the shaft portion of the channel,
wherein the inlet of the channel is open to a space above the container.

2. The immersion tank of claim 1, wherein the channel further includes a vapor duct located above the shaft portion and a liquid funnel located below the shaft portion, wherein the vapor duct includes the inlet of the channel, and wherein the liquid funnel includes the outlet of the channel.

3. The immersion tank of claim 2, wherein the vapor duct is formed at least by an upper portion of the outer wall of the immersion tank.

4. The immersion tank of claim 3, wherein the vapor duct is further formed by a lateral portion of the outer wall of the immersion tank.

5. The immersion tank of claim 3, wherein the vapor duct includes a high spot formed by an upset of the upper portion of the outer wall of the immersion tank.

6. The immersion tank of claim 3, wherein height of the vapor duct is at least as large as a width of one condenser.

7. The immersion tank of claim 2, wherein the shaft portion is formed at least by one or more divider plates located inside the outer wall.

8. The immersion tank of claim 7, wherein the shaft portion is further formed by a lateral portion of the outer wall.

9. The immersion tank of claim 7, wherein the shaft portion is vertical.

10. The immersion tank of claim 2, wherein the liquid funnel is formed at least by a base portion of one or more divider plates located inside the immersion tank.

11. The immersion tank of claim 10, wherein the liquid funnel is further formed by a lateral portion of the outer wall of the immersion tank.

12. The immersion tank of claim 11, wherein the lateral portion of the outer wall is slanted.

13. The immersion tank of claim 10, wherein the outlet of the channel is formed by one or more openings provided through the base portion of the one or more divider plates.

14. The immersion tank of claim 1, wherein the immersion tank has, in a lateral direction, a first zone, and a second zone located on a side of the first zone, and in a vertical direction, a lower space, a middle space, and an upper space, wherein the container is located in the first zone and in the lower space, wherein the one or more condenser are located in the second zone and in the middle space.

15. The immersion tank of claim 14, wherein the channel is formed at least by one or more divider plate located inside the outer wall and forming an essentially vertical barrier between the first zone and the second zone, wherein one or more opening are provided at a base portion of one or more divider plate.

16. The immersion tank of claim 15, wherein the one or more divider plate extends vertically from a slanted portion of the outer wall of the immersion tank to at least a level approximately as high as a top of one condenser.

17. The immersion tank of claim 15, wherein the one or more divider plate extends axially along an entire length of the immersion tank.

18. The immersion tank of claim 15, wherein a top of the one or more divider plate is offset from a top of the immersion tank by at least a width of one condenser.

19. A method of using an immersion tank for a two-phase immersion cooling system, comprising:
holding a bath of dielectric heat transfer fluid in liquid phase in a container provided within an outer wall forming the immersion tank;
flowing the dielectric heat transfer fluid in vapor phase through a channel provided within the outer wall in a generally downward direction; and
condensing the dielectric heat transfer fluid in vapor phase using one or more condenser snuggly fitted in a shaft portion of the channel.

20. An immersion tank for a two-phase immersion cooling system, comprising:
an outer wall forming the immersion tank;
a container for holding a bath of dielectric heat transfer fluid in liquid phase;
at least one condenser for condensing dielectric heat transfer fluid from a vapor phase to a liquid phase; and
a divider plate configured such that a dielectric heat transfer vapor is directed to enter into a top of the at least one condenser and the dielectric heat transfer vapor flows downward though the at least one condenser.

21. The immersion tank of claim 20 wherein the divider plate is further configured such that the dielectric heat transfer vapor is hindered from entering a bottom of the condenser.

22. The immersion tank of claim 20 wherein the at least one condenser includes a plurality of serpentine coils, and a plurality of transverse fins that span essentially over an entire height of the one or more condenser.
